(19) United States
(12) Patent Application Publication
(10) Pub. No.: US 2019/0066765 A1
(43) Pub. Date: Feb. 28, 2019

(54) DRAM AND METHOD FOR OPERATING THE SAME

(71) Applicant: NANYA TECHNOLOGY CORPORATION, New Taipei City (TW)

(72) Inventors: Chung-Hsun LEE, NEW TAIPEI CITY (TW); Hsien-Wen LIU, LUZHU TOWNSHIP, TAOYUAN COUNTY (TW)

(21) Appl. No.: 15/684,524

(22) Filed: Aug. 23, 2017

(51) Int. Cl. G11C 11/406; G06F 3/06; G11C 11/408

(52) U.S. Cl. CPC G11C 11/40611; G06F 3/062; G11C 11/408; G06F 3/0659; G06F 3/0683; G06F 3/0647

(57) ABSTRACT

The present disclosure provides a DRAM including a first refresh unit, a second refresh unit, and a control device. The first refresh unit has a first quantity of valid data. The second refresh unit has a second quantity of valid data less than the first quantity of valid data. The control device is configured to determine that the first refresh unit has a greater quantity of valid data than the second refresh unit, move valid data of the second refresh unit into the first refresh unit, and cease refreshing the second refresh unit whose valid data was moved into the first refresh unit.

### TECHNICAL FIELD

The present disclosure relates to a dynamic random access memory (DRAM), and more particularly, to a DRAM and method for operating a DRAM.

### DISCUSSION OF THE BACKGROUND

Dynamic random access memory (DRAM) is a type of random access memory that stores each bit of data in a separate capacitor. A simplest DRAM cell comprises a single N-type metal-oxide-semiconductor (NMOS) transistor and a single capacitor. If charge is stored in the capacitor, the cell is said to store a logic HIGH, depending on the convention used. If no charge is present, the cell is said to store a logic LOW. Because the charge in the capacitor dissipates over time, DRAM systems require additional refreshing circuitries to periodically refresh the charge stored in the capacitors. Since a capacitor can store only a very limited amount of charge, in order to quickly distinguish the difference between a logic 1 and a logic 0, two bit lines (BLs) are typically used for each bit, wherein the first in the bit line pair is known as a bit line true (BLT) and the other is the bit line complement (BLC). The single NMOS transistor's gate is controlled by a word line (WL).

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a DRAM. The DRAM includes a first refresh unit having a first quantity of valid data; a second refresh unit having a second quantity of valid data less than the first quantity of valid data; and a control device configured to determine that the first refresh unit has a greater quantity of valid data than the second refresh unit, move valid data of the second refresh unit into the first refresh unit, and cease refreshing the second refresh unit whose valid data was moved into the first refresh unit.

In some embodiments, the control device is configured to continue refreshing the first refresh unit which stores the moved valid data.

In some embodiments, the control device is configured to move valid data of the second refresh unit into the first refresh unit by providing to the first refresh unit the same valid data as that of the second refresh unit.

In some embodiments, the control device is configured to move valid data of the second refresh unit into the first refresh unit during refreshing the second refresh unit.

In some embodiments, the control device is configured to establish an updated relationship between a logical address and an updated physical address associated with the moved valid data, and access the first refresh unit based on the updated relationship when the control device is to access the moved valid data.

In some embodiments, the control device is configured to remove a relationship between the logical address and an initial physical address associated with valid data of the second refresh unit when the control device establishes the updated relationship.

In some embodiments, the DRAM includes a third refresh unit having a third quantity of valid data, wherein the second quantity of valid data is greater than the third quantity of valid data. The control device is further configured to determine that the first refresh unit has the greatest quantity of valid data. When the control device determines that capacity of the first refresh unit is sufficient to store all of valid data of the second refresh unit and the third refresh unit, the control device move the all of valid data to the first refresh unit, ceases refreshing the second refresh unit and the third refresh unit, and continues refreshing the first refresh unit.

In some embodiments, the DRAM further includes a third refresh unit having a third quantity of valid data, wherein the second quantity of valid data is greater than the third quantity of valid data, wherein the control device is further configured to determine that the first refresh unit has the greatest quantity of valid data, and the second refresh unit has the second greatest quantity of valid data, and wherein when the control device determines that the first refresh unit has sufficient capacity to store all of valid data of only the third refresh unit, the control device moves the all of valid data to the first refresh unit, ceases refreshing the third refresh unit, and continues refreshing the first refresh unit and the second refresh unit.

In some embodiments, the DRAM further includes a third refresh unit having a third quantity of valid data less than the second quantity of valid data, wherein the control device is further configured to determine that the first refresh unit has the greatest quantity of valid data, and the second refresh unit has the second greatest quantity of valid data, and wherein when the control device determines that capacity of the first refresh unit is not sufficient to store all of valid data of only the third refresh unit, the control device moves a portion of the all of valid data into the first refresh unit and moves the remaining portion of the all of valid data into the second refresh unit, ceases refreshing the third refresh unit, and continues refreshing the first refresh unit and the second refresh unit.

Another aspect of the present disclosure provides a DRAM. The DRAM includes a first refresh unit having a first quantity of valid data; a second refresh unit having a second quantity of valid data; a third refresh unit having a third quantity of valid data; and a control device configured to determine, based on the first quantity, the second quantity and the third quantity, which one of the first refresh unit, the second refresh unit and the third refresh unit serves as a destination refresh unit, into which valid data of the other two refresh units are moved, determine, based on the first quantity, the second quantity and the third quantity, which valid data of one of the other two refresh units has a higher priority to be moved into the destination refresh unit than the other one of the other two refresh units, perform, based on the determinations, a centralization operation on the first refresh unit, the second refresh unit and the third refresh unit, continue refreshing the destination refresh unit, and cease refreshing refresh units not identified as the destination refresh unit.

In some embodiments, when the first quantity of valid data is greater than both the second quantity of valid data and the third quantity of valid data, the control device determines that the first refresh unit is the destination refresh unit.

In some embodiments, when the second quantity of valid data is greater than the third quantity of valid data, the control device determines that valid data of the third refresh unit has higher priority than valid data of the second refresh unit.

Another aspect of the present disclosure provides a method. The method includes determining that a first refresh unit has a greater quantity of valid data than a second refresh unit; moving valid data of the second refresh unit into the first refresh unit; and ceasing refreshing the second refresh unit whose valid data was moved into the first refresh unit.

In some embodiments, the method further includes refreshing the first refresh unit storing the moved valid data.

In some embodiments, the moving valid data stored in the second refresh unit into the first refresh unit includes moving valid data of the second refresh unit into the first refresh unit by providing to the first refresh unit the same valid data as that of the second refresh unit.

In some embodiments, the moving valid data of the second refresh unit into the first refresh unit includes moving valid data of the second refresh unit into the first refresh unit during refreshing the second refresh unit.

In some embodiments, the method further includes establishing an updated relationship between a logical address and an updated physical address associated with the moved valid data; and accessing the first refresh unit based on the updated relationship when the moved valid data is to be accessed.

In some embodiments, the method further includes determining that the first refresh unit has the greatest quantity of valid data; moving all of valid data of the second refresh unit and the third refresh unit to the first refresh unit when it is determined that capacity of the first refresh unit is sufficient to store the all of valid data; ceasing refreshing the second refresh unit when it is determined that capacity of the first refresh unit is sufficient to store the all of valid data; and continuing to refresh the first refresh unit when it is determined that capacity of the first refresh unit is sufficient to store the all of valid data.

In some embodiments, the method further includes determining that the first refresh unit has the greatest quantity of valid data; determining that the second refresh unit has the second greatest quantity of valid data; moving all of valid data of only the third refresh unit to the first refresh unit when it is determined that capacity of the first refresh unit is sufficient to store the all of valid data of the third refresh unit; ceasing refreshing the third refresh unit when it is determined that capacity of the first refresh unit is sufficient to store the all of valid data of the third refresh unit; and continuing to refresh the first refresh unit and the second refresh unit when it is determined that capacity of the first refresh unit is sufficient to store the all of valid data of the third refresh unit.

In some embodiments, the method further includes determining that the first refresh unit has the greatest quantity of valid data; determining that the second refresh unit has the second greatest quantity of valid data; moving a portion of all of valid data of the third refresh unit into the first refresh unit when it is determined that capacity of the first refresh unit is not sufficient to store the all of valid data of the third refresh unit; moving the remaining portion of the all of valid data stored in the third refresh unit into the second refresh unit when it is determined that capacity of the first refresh unit is not sufficient to store the all of valid data of the third refresh unit; ceasing refreshing the third refresh unit when it is determined that the capacity of the first refresh unit is not sufficient to store the all of valid data; and continuing to refresh the first refresh unit and the second refresh unit when it is determined that the capacity of the first refresh unit is not sufficient to store the all of valid data.

In the present disclosure, the control device is able to centralize valid data from the second refresh unit and the third refresh unit to the first refresh unit. After the centralization operation is completed, the control device ceases refreshing the second refresh unit and the third refresh unit, which no longer store any valid data. As a result, the memory device has relatively high power efficiency. Moreover, the control device is further able to determine which refresh unit has a higher priority to serve as a destination refresh unit, and able to determine which refresh unit's valid data has a higher priority to be centralized. As such, relatively few write and read operations are performed. As a result, the memory device is even more power efficient.

In some existing DRAM devices, a DRAM controller of the DRAM device is unable to perform the centralization operation, and refreshes all refresh units in the DRAM device despite the DRAM device being in a power saving mode. As a result, the existing DRAM devices have relatively low power efficiency.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a block diagram of a dynamic random access memory (DRAM) system, in accordance with some embodiments of the present disclosure.

FIG. 2 is a block diagram illustrating a capacity status of the memory device shown in FIG. 1, in accordance with some embodiments of the present disclosure.

FIG. 3 is a block diagram illustrating a centralization operation of the memory device shown in FIG. 1 based on the capacity status shown in FIG. 2, in accordance with some embodiments of the present disclosure.

FIG. 4 is a block diagram illustrating a refresh operation of the memory device shown in FIG. 1 after the centralization operation shown in FIG. 3, in accordance with some embodiments of the present disclosure.

FIG. 5 is a flow diagram of a method, in accordance with some embodiments of the present disclosure.

FIG. 6 is a block diagram of a dynamic random access memory (DRAM) system, in accordance with some embodiments of the present disclosure.

FIG. 7 is a block diagram illustrating a capacity status of the memory device shown in FIG. 6, in accordance with some embodiments of the present disclosure.

FIG. 8 is a block diagram illustrating a centralization operation of the memory device shown in FIG. 6 based on the capacity status is shown in FIG. 7, in accordance with some embodiments of the present disclosure.

FIG. 9 is a block diagram illustrating a refresh operation of the memory device shown in FIG. 6 after the centralization operation shown in FIG. 8, in accordance with some embodiments of the present disclosure.

FIG. 10 is a block diagram of a dynamic random access memory (DRAM) system, in accordance with some embodiments of the present disclosure.

FIG. 11 is a block diagram illustrating a capacity status of the memory device shown in FIG. 10, in accordance with some embodiments of the present disclosure.

FIG. 12 is a block diagram illustrating a centralization operation of the memory device shown in FIG. 10 based on the capacity status shown in FIG. 11, in accordance with some embodiments of the present disclosure.

FIG. 13 is a block diagram illustrating a refresh operation of the memory device shown in FIG. 10 after the centralization operation shown in FIG. 12, in accordance with some embodiments of the present disclosure.

FIG. 14 is a flow diagram of another method, in accordance with some embodiments of the present disclosure.

FIG. 15 is a flow diagram of yet another method, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

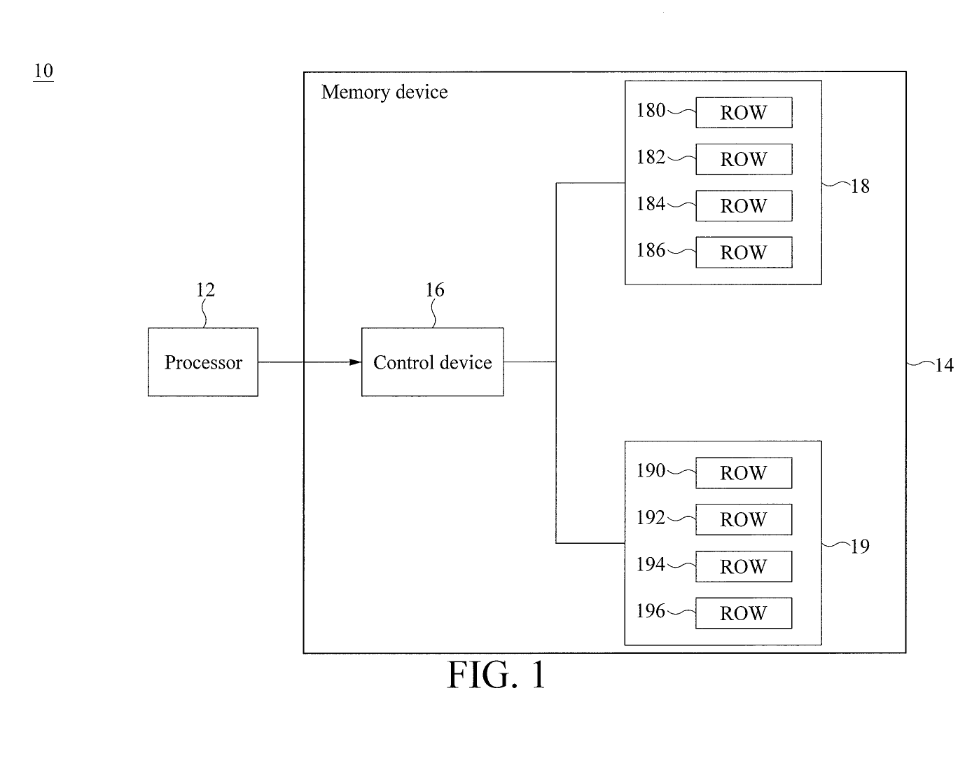

FIG. 1 is a block diagram of a dynamic random access memory (DRAM) system 10, in accordance with some embodiments of the present disclosure. Referring to FIG. 1, the DRAM system 10 includes a processor 12 and a memory device 14 controllable by the processor 12. In an embodiment, the processor 12 includes a central processing unit (CPU) or part of a computing module.

The memory device 14 includes a control device 16, and a first refresh unit 18 and a second refresh unit 19 controllable by the control device 16. In an embodiment, the control device 16 is placed out of the memory device 14, or integrated with the processor 12.

The first refresh unit 18 functions to store data. In further detail, the first refresh unit 18 includes rows 180, 182, 184 and 186, each of which controls the associated memory cells for storing the data, and each of the rows 180, 182, 184 and 186 is controllable by the control device 16. For convenience of discussion, in the following context, when it is stated that a row stores a data, such statement indicates that memory cells of the row store the data. Circuit structure, connection and operation between, for example, the row 180 and the associated memory cells are well known. Consequently, detailed descriptions are omitted herein. In the present disclosure, the first refresh unit 18 includes more rows than one. However, the present disclosure is not limited thereto. In some embodiments, the first refresh unit 18 includes one row. Additionally, in the present embodiment, rows 180, 182, 184 and 186 are arranged in the same bank of the memory device 14. However, the present disclosure is not limited thereto.

The second refresh unit 19 functions to store data. In further detail, the second refresh unit 19 includes rows 190, 192, 194 and 196, each of which controls the associated memory cells for storing the data, and each of the rows 190, 192, 194 and 196 is controllable by the control device 16. Circuit structure, connection and operation between, for example, the row 190 and the associated memory cells are well known. Consequently, detailed descriptions are omitted herein. In the present disclosure, the second refresh unit 19 includes more rows than one. However, the present disclosure is not limited thereto. In some embodiments, the second refresh unit 19 includes one row. Additionally, in the present embodiment, rows 190, 192, 194 and 196 are arranged in the same bank of the memory device 14. However, the present disclosure is not limited thereto.

It should be noted that in the following discussion, the number of refresh units and the number of rows only serve as an example. The present disclosure is not limited thereto.

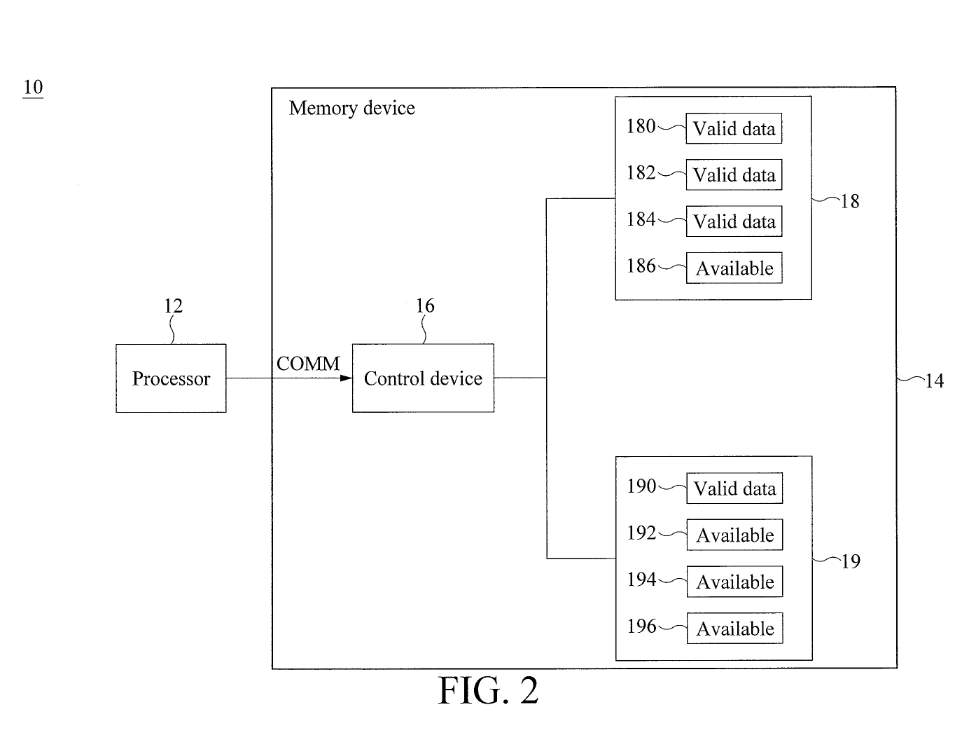

FIG. 2 is a block diagram illustrating a capacity status of the memory device 10 shown in FIG. 1, in accordance with some embodiments of the present disclosure. Referring to FIG. 2, the first refresh unit 18 stores a first quantity of valid data. In further detail, in the first refresh unit 18, the rows 180, 182 and 184 store valid data, and the row 186 is available. The second refresh unit 19 stores a second quantity of valid data. In further detail, in the second refresh unit 19, the row 190 stores valid data, and the rows 192, 194 and 196 are available.

In the present disclosure, a status of a row being available means that the row stores no data, or a data stored by the row is an invalid data.

In the present disclosure, the memory device 14 functions to temporarily store data. If the data is a data, which will be used during execution of a program, the data is called a valid data. If not, the data is called an invalid data.

The memory device 14 is unable to determine, on its own, which data is valid or invalid. Instead, the memory device 14 identifies whether data is valid based on a command COMM from the processor 12. In further detail, the command COMM includes an information on an address of a row which stores valid data. As such, the control device 16 of the memory device 14 is able to determine which data is valid based on the address derived from the command COMM.

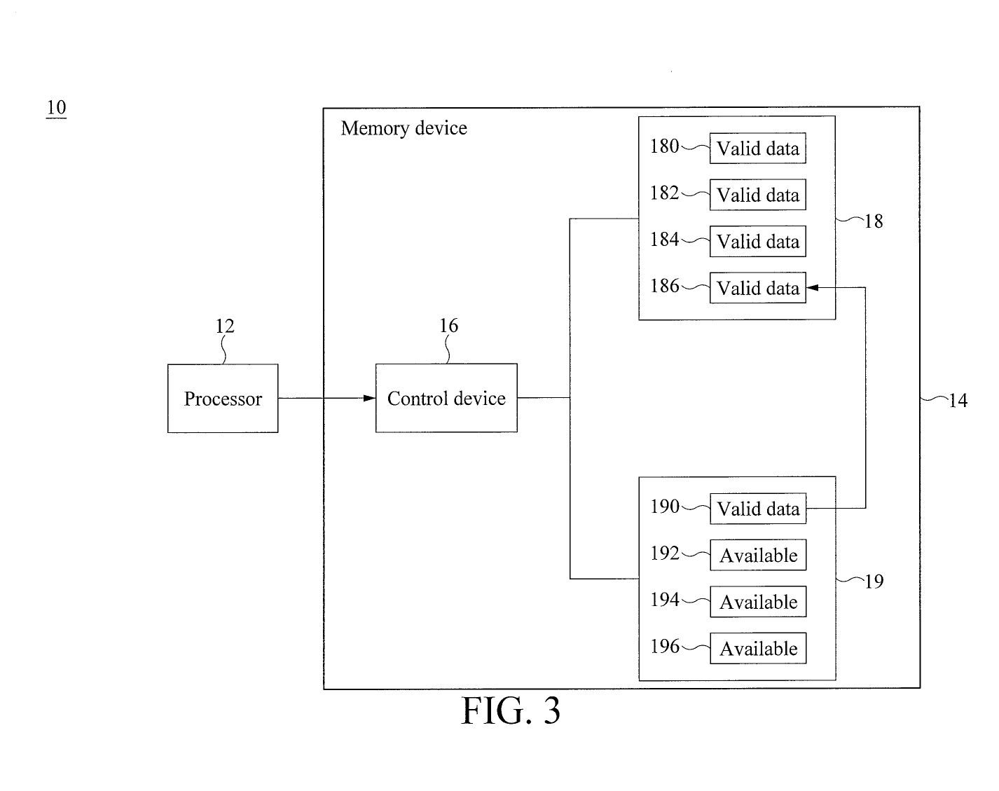

FIG. 3 is a block diagram illustrating a centralization operation of the memory device 14 shown in FIG. 1 based on the capacity status shown in FIG. 2, in accordance with some embodiments of the present disclosure. Referring to FIG. 3, the control device 16 determines that the first refresh unit 18 stores a greater quantity of valid data than the second refresh unit 19. Next, the control device 16 centralizes valid data stored in the second refresh unit 19 into the first refresh unit 18. However, the present disclosure is not limited thereto. In some embodiments, the control device 16 centralizes valid data stored in the first refresh unit 18 to the second refresh unit 19.

Compared to an embodiment of centralizing valid data stored in a refresh unit with a greater quantity of valid data into a refresh unit with a smaller quantity of valid data, in the embodiment of centralizing valid data stored in a refresh unit with a smaller quantity of valid data into a refresh unit with a greater quantity of valid data, for example, fewer write operations are required to write valid data to be centralized. As a result, power consumption is relatively efficient.

In an embodiment, the control device 16 centralizes valid data stored in the second refresh unit 19 into the first refresh unit 18 by providing to the first refresh unit 19 the same valid data as that stored in the second refresh unit 18. In another embodiment, the control device 16 centralizes valid data stored in the second refresh unit 19 into the first refresh unit 18 during refreshing the second refresh unit 19.

In an embodiment, after the data is centralized into the first refresh unit 18, the control device 16 establishes an updated relationship between a logical address and an updated physical address associated with the centralized valid data. The updated relationship in the embodiment of FIG. 3 is shown in Table 1 below. For convenience of discussion, a numeral of a row may refer to the row, or may refer to a valid data stored therein when appropriate. For example, the numeral 190 may refer to the row 190, or may refer to the valid data 190 when appropriate.

TABLE 1

| logical address | updated physical address |
|---|---|
| LA_01 | PA_05 |

Where LA_01 represents a logical address associated with the valid data 190; and PA_05 represents a physical address of the row 186 where the valid data 190 is centralized.

When the control device 16 is to access the centralized valid data 190, the control device 16 accesses the row 186 of the first refresh unit 18 based on the updated relationship, instead of the row 190 of the second refresh unit 19.

In an embodiment, the control device 16 removes a relationship between the logical address and an initial physical address associated with valid data stored in the second refresh unit when the control device establishes the updated relationship. The relationship in the embodiment of FIG. 3 is shown in Table 2 below.

TABLE 2

| logical address | initial physical address |
|---|---|
| LA_01 | PA_09 |

Where LA_01 represents a logical address associated with the valid data 190; and PA_09 represents an initial physical address of the row 190 where the valid data 190 is stored before the valid data 190 is centralized.

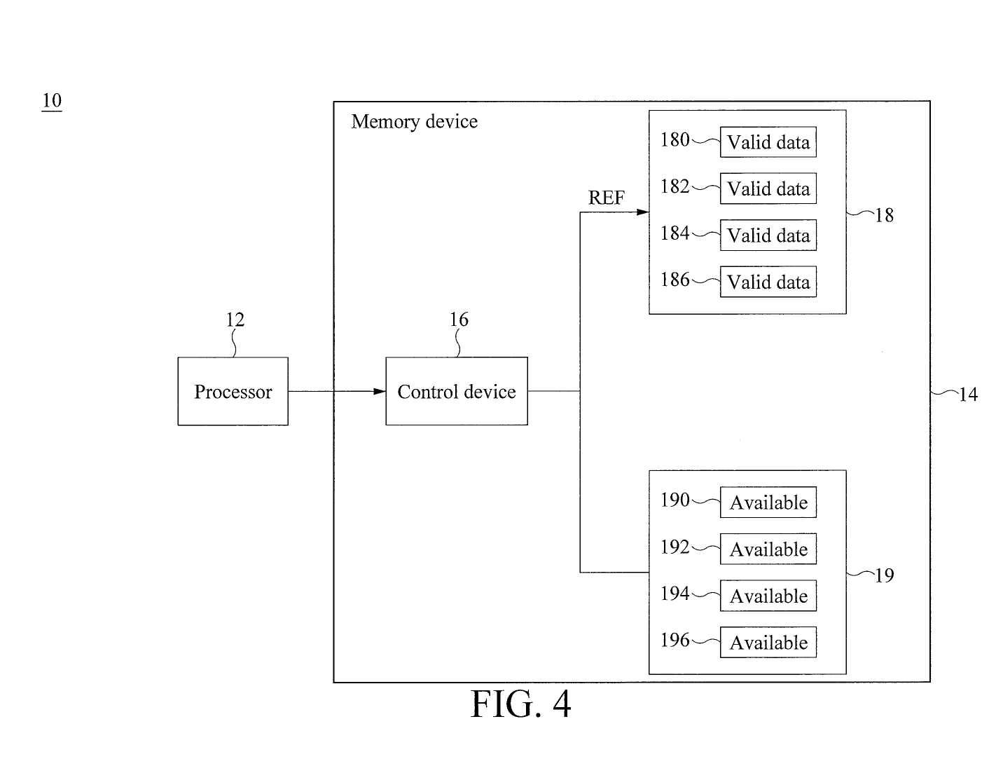

FIG. 4 is a block diagram illustrating a refresh operation of the memory device 14 shown in FIG. 1 after the centralization operation shown in FIG. 3, in accordance with some embodiments of the present disclosure. Referring to FIG. 4, the control device 16 ceases refreshing the second refresh unit 19 whose valid data was centralized into the first refresh unit 18. Moreover, the control device 16 continues refreshing the first refresh unit 18, which stores the centralized valid data 190 in the row 186.

In the present disclosure, the control device 16 is able to centralize valid data from the second refresh unit 19 to the first refresh unit 18 (or, from the first refresh unit 18 to the second refresh unit 18). After the centralization operation is completed, the control device 16 ceases refreshing the second refresh unit 19, which no longer stores any valid data. As a result, the memory device 14 has relatively high power efficiency. Moreover, the control device 16 is further able to determine the quantity of valid data in each of the refresh units, the first refresh unit 18 and the second refresh unit 19. The control device 16, based on the determination, centralizes valid data stored in the second refresh unit 19, which stores a smaller quantity of valid data into the first refresh unit 18, which stores a relatively large quantity of valid data. As such, relatively few write and read operations are performed. As a result, the memory device 14 is even more power efficient.

In some existing DRAM devices, a DRAM controller of the DRAM device is unable to perform the centralization operation, and refreshes all of the refresh units in the DRAM device despite the DRAM device being in a power saving mode. As a result, the existing DRAM devices have relatively low power efficiency.

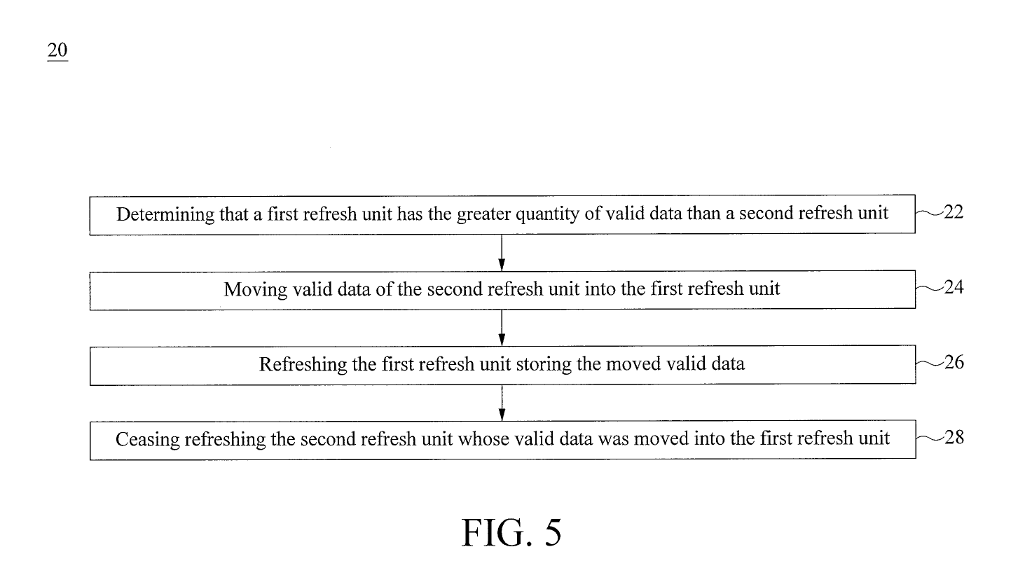

FIG. 5 is a flow diagram of a method 20, in accordance with some embodiments of the present disclosure. Referring to FIG. 5, the method 20 includes operations 22, 24, 26 and 28. The method 20 begins with operation 22, in which it is determined that a first refresh unit stores a greater quantity of valid data than a second refresh unit. The method 20 continues with operation 24, in which valid data stored in the second refresh unit is centralized into the first refresh unit. The method 20 proceeds to operation 26, in which the first refresh unit, which stores the centralized valid data, is refreshed. The method 20 concludes with operation 28, in which the second refresh unit, whose valid data was centralized into the first refresh unit, ceases to be refreshed.

In the present disclosure, valid data is able to be centralized from the second refresh unit to the first refresh unit. After the centralization operation is completed, the second refresh unit, which no longer stores any valid data, ceases to be refreshed. As a result, by using the method 20 to operate a memory device, the memory device has relatively high power efficiency. Moreover, the quantity of valid data stored in each of the refresh units can be determined. Valid data stored in the second refresh unit, which stores a smaller quantity of valid data, is centralized into the first refresh unit, which stores a greater quantity of valid data. As a result, the memory device is even more power efficient.

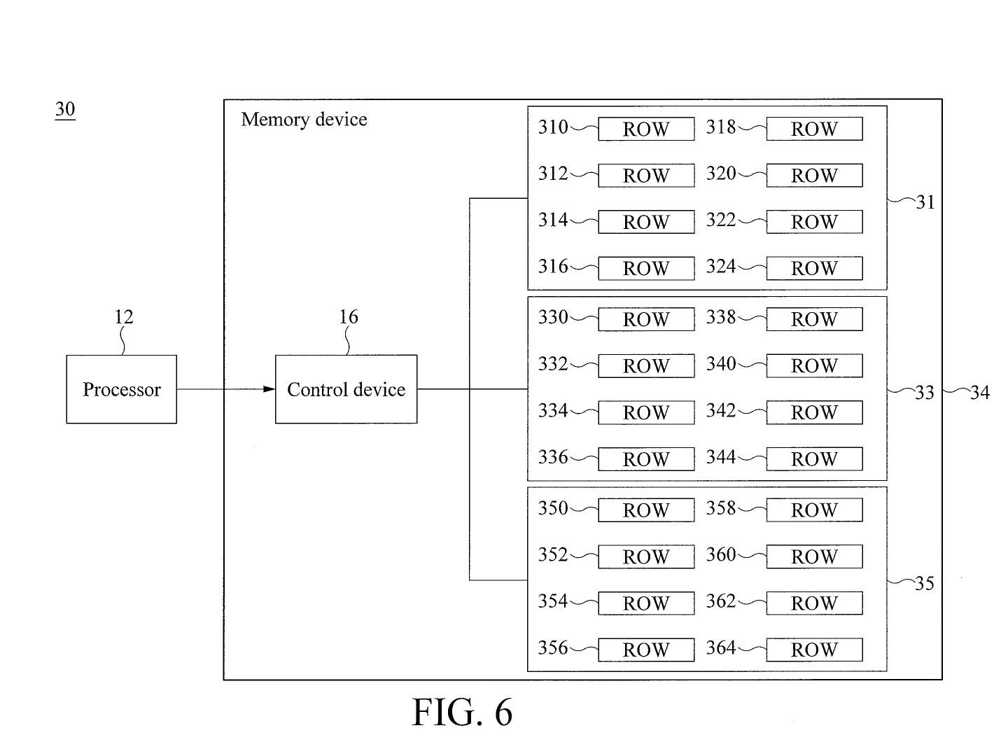

FIG. 6 is a block diagram of a dynamic random access memory (DRAM) system 30, in accordance with some embodiments of the present disclosure. Referring to FIG. 6, the DRAM system 30 is similar to the DRAM system 10 described and illustrated with reference to FIG. 1 except that, for example, the DRAM system 30 includes a memory device 34 including a first refresh unit 31, a second refresh unit 33, and a third refresh unit 35.

The first refresh unit 31 functions to store data. In further detail, the first refresh unit 31 includes rows 310, 312, 314, 316, 318, 320, 322 and 324, each of which controls the associated memory cells for storing the data, and each of the rows 310, 312, 314, 316, 318, 320, 322 and 324 is controllable by the control device 16.

The second refresh unit 33 functions to store data. In further detail, the second refresh unit 33 includes rows 330, 332, 334, 336, 338, 340, 342 and 344, each of which controls the associated memory cells for storing the data, and each of the rows 330, 332, 334, 336, 338, 340, 342 and 344 is controllable by the control device 16.

The third refresh unit 35 functions to store data. In further detail, the third refresh unit 35 includes rows 350, 352, 354, 356, 358, 360, 362 and 364, each of which controls the associated memory cells for storing the data, and each of the rows 350, 352, 354, 356, 358, 360, 362 and 364 is controllable by the control device 16.

Descriptions of the first refresh unit 31, the second refresh unit 33 and the third refresh unit 35 are similar to descriptions of the first refresh unit 18 and the second refresh unit 19 described above and illustrated with reference to FIGS. 1 to 4. Therefore, the detailed descriptions are omitted herein.

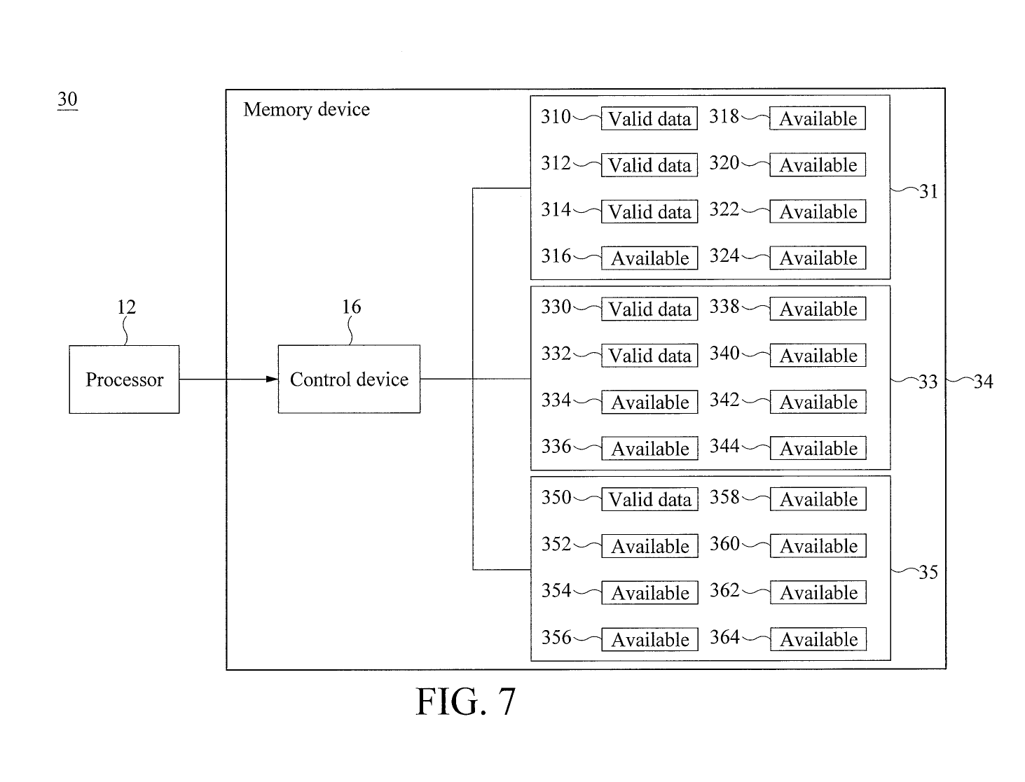

FIG. 7 is a block diagram illustrating a capacity status of the memory device 30 shown in FIG. 6, in accordance with some embodiments of the present disclosure. Referring to FIG. 7, the first refresh unit 31 stores a first quantity of valid data. In further detail, in the first refresh unit 31, the rows 310, 312 and 314 store valid data, and the rows 316, 318, 320, 322 and 324 are available. The second refresh unit 33 stores a second quantity of valid data. In further detail, in the second refresh unit 33, the rows 330 and 332 store valid data, and the rows 334, 336, 338, 340, 342 and 344 are available. The third refresh unit 35 stores a third quantity of valid data. In further detail, in the third refresh unit 35, the row 350 stores valid data, and the rows 352, 354, 356, 358, 360, 362 and 364 are available.

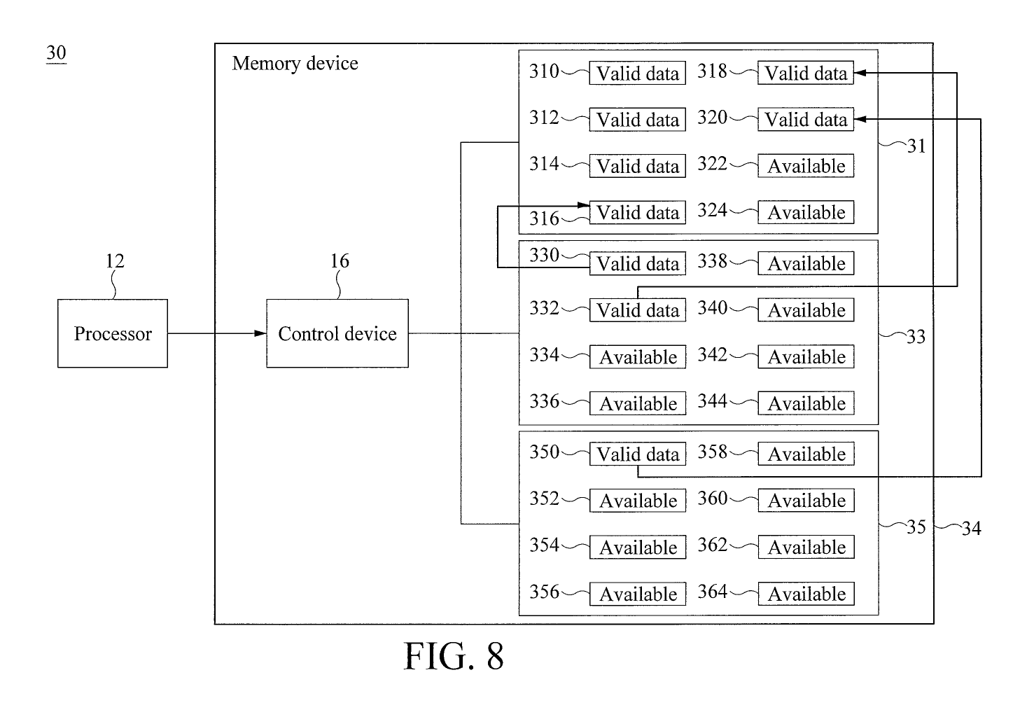

FIG. 8 is a block diagram illustrating a centralization operation of the memory device 30 shown in FIG. 6 based on the capacity status shown in FIG. 7, in accordance with some embodiments of the present disclosure. Referring to FIG. 8, the control device 16 determines that the first refresh unit 31 stores the greatest quantity of valid data, the second refresh unit 33 stores the second greatest quantity of valid data, and the third refresh unit 35 stores the smallest quantity of valid data. Accordingly, the control device 16 determines that the first refresh unit 31 has highest priority to serve as a destination refresh unit, and the second refresh unit 33 has a middle priority to serve as the destination refresh unit. In further detail, because the first refresh unit 31 has the highest priority, valid data is centralized to the first refresh unit 31 first. Next, if capacity of the first refresh unit 31 is not sufficient to store all of valid data to be centralized, a portion of the all of valid data is centralized into the second refresh unit 33, which has the middle priority.

Moreover, since the second refresh unit 33 stores the second greatest quantity of valid data, and the third refresh unit 35 stores the smallest quantity of valid data, valid data of the third refresh unit 35 has a higher priority to be centralized into the destination refresh unit than valid data of the second refresh unit 33.

In operation, the control device 16 determines that capacity of the first refresh unit 33 is sufficient to store all of valid data stored in the second refresh unit 33 and the third refresh unit 35. Accordingly, the control device 16 centralizes the all of valid data to the first refresh unit 31. In further detail, the control device 16 centralizes valid data stored in the rows 350, 330 and 332 (in the second and third refresh units 33 and 35) to the rows 320, 316 and 318 in the first refresh unit 31, respectively.

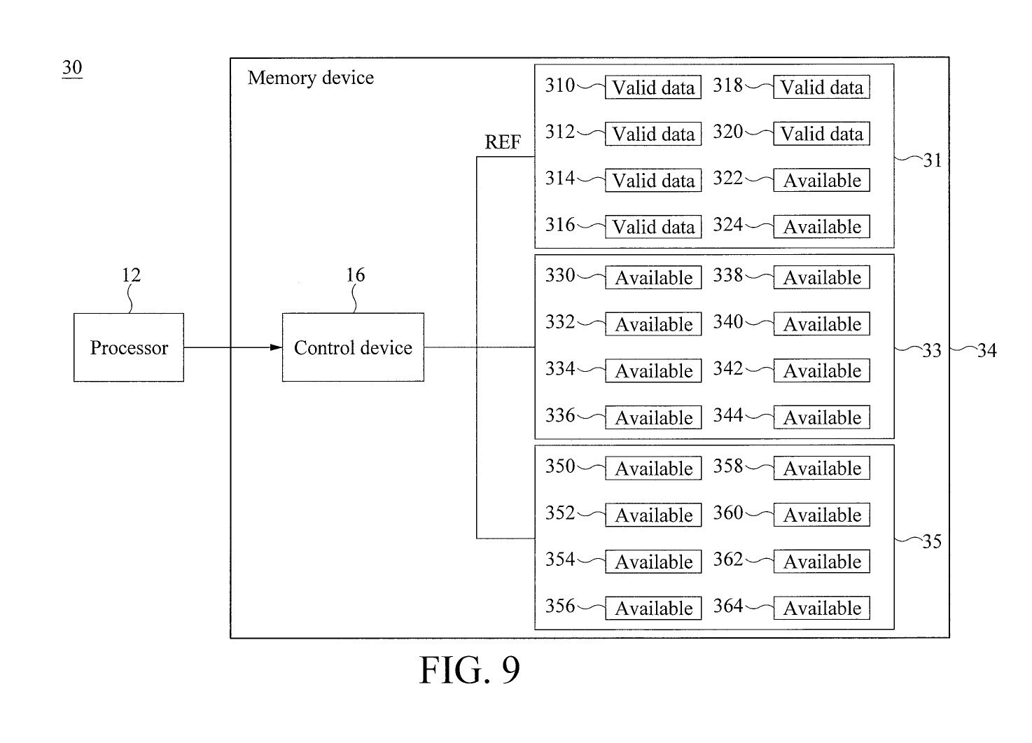

FIG. 9 is a block diagram illustrating a refresh operation of the memory device 30 shown in FIG. 6 after the centralization operation shown in FIG. 8, in accordance with some embodiments of the present disclosure. Referring to FIG. 9, the control device 16 ceases refreshing the second refresh unit 33 and the third refresh unit 35 and continues refreshing the first refresh unit 31, which serves as the destination refresh unit.

In the present disclosure, the control device 16 is able to centralize valid data from the second refresh unit 33 and the third refresh unit 35 to the first refresh unit 31. After the centralization operation is completed, the control device 16 ceases refreshing the second refresh unit 33 and the third refresh unit 35, which no longer store any valid data. As a result, the memory device 34 has relatively high power efficiency. Moreover, the control device 16 is further able to determine which refresh unit has priority to serve as a destination refresh unit, and the control device 16 is able to determine which refresh unit's valid data has a higher priority to be centralized. As such, relatively few write and read operations are performed. As a result, the memory device 34 is even more power efficient.

In some existing DRAM devices, a DRAM controller of the DRAM device is unable to perform the centralization operation, and refreshes all refresh units in the DRAM device despite the DRAM device being in a power saving mode. As a result, the existing DRAM devices have relatively low power efficiency.

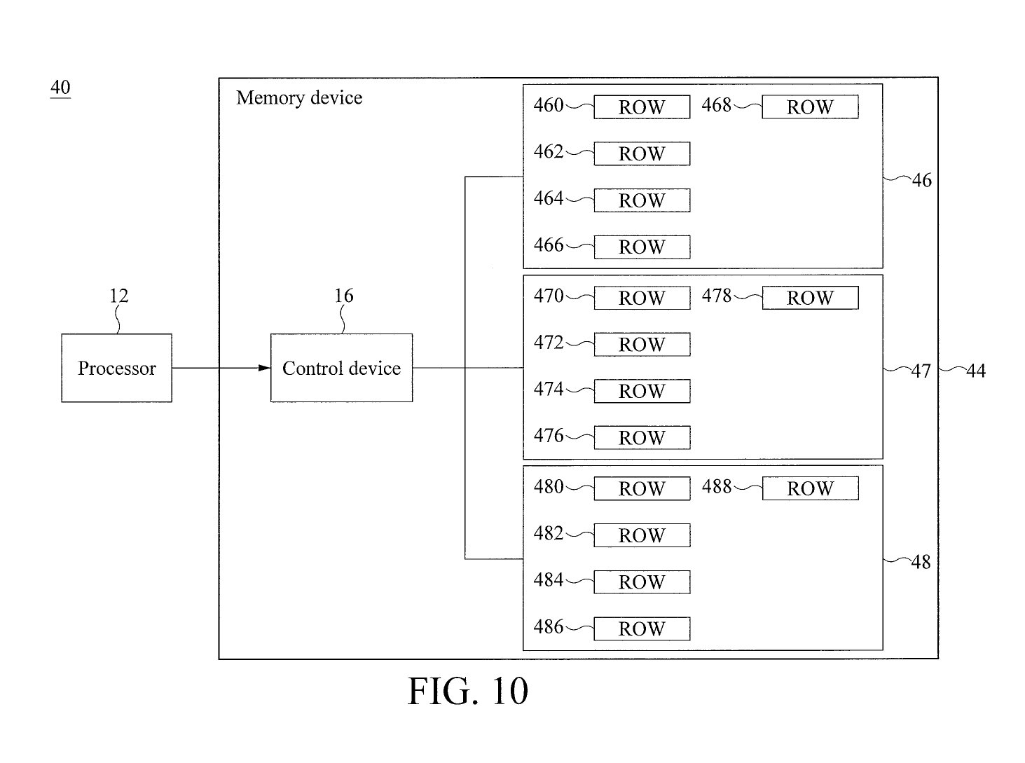

FIG. 10 is a block diagram of a dynamic random access memory (DRAM) system 40, in accordance with some embodiments of the present disclosure. Referring to FIG. 10, the DRAM system 40 is similar to the DRAM system 10 described and illustrated with reference to FIG. 1 except that, for example, the DRAM system 40 includes a memory device 44 including a first refresh unit 46, a second refresh unit 47 and a third refresh unit 48.

The first refresh unit 46 functions to store data. In further detail, the first refresh unit 46 includes rows 460, 462, 464, 466 and 468, each of which controls the associated memory cells for storing the data, and each of the rows 460, 462, 464, 466 and 468 is controllable by the control device 16.

The second refresh unit 47 functions to store data. In further detail, the first refresh unit 47 includes rows 470, 472, 474, 476 and 478, each of which controls the associated memory cells for storing the data, and each of the rows 470, 472, 474, 476 and 478 is controllable by the control device 16.

The third refresh unit 48 functions to store data. In further detail, the third refresh unit 48 includes rows 480, 482, 484, 486 and 488, each of which controls the associated memory cells for storing the data, and each of the rows 480, 482, 484, 486 and 488 is controllable by the control device 16.

Descriptions of the first refresh unit 46, the second refresh unit 47 and the third refresh unit 48 are similar to descriptions of the first refresh unit 18 and the second refresh unit 19 described and illustrated with reference to FIGS. 1 to 4. Therefore, the detailed descriptions are omitted herein.

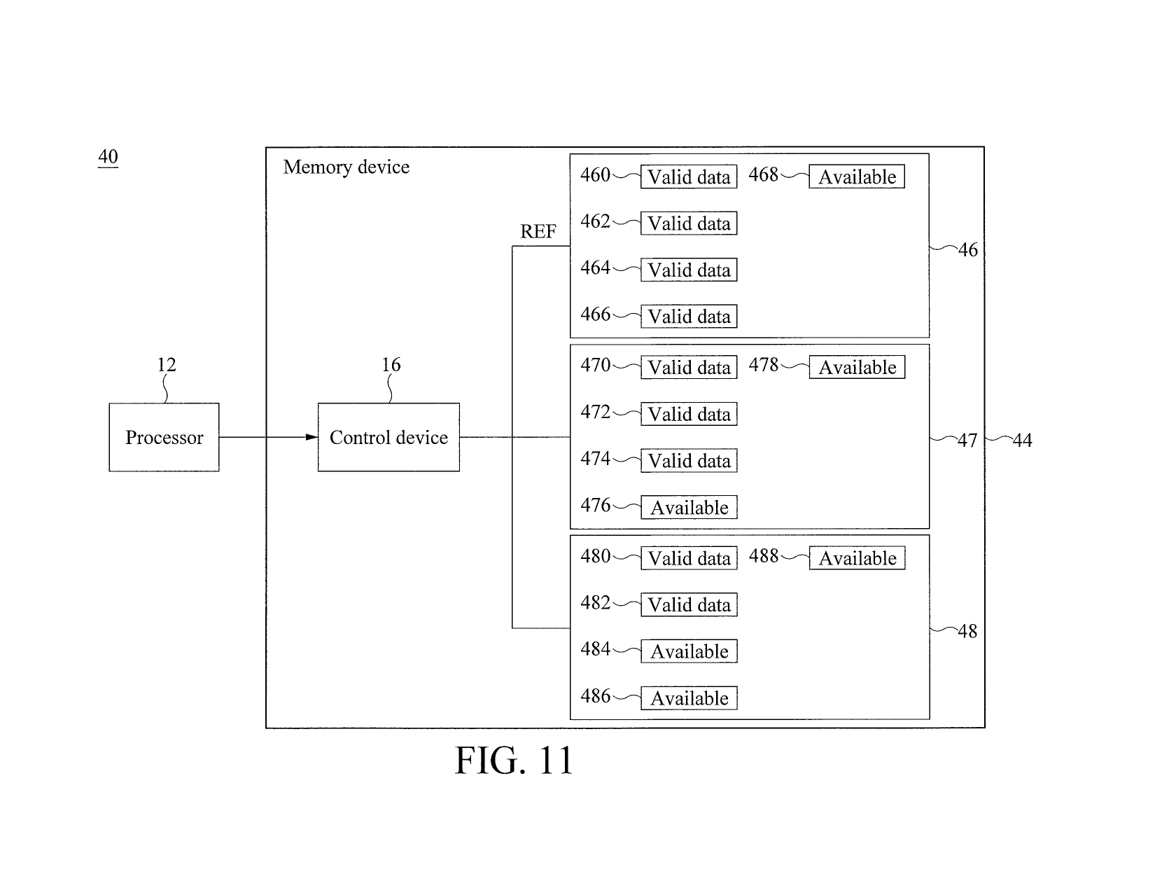

FIG. 11 is a block diagram illustrating a capacity status of the memory device 40 shown in FIG. 10, in accordance with some embodiments of the present disclosure. Referring to FIG. 11, the first refresh unit 46 stores a first quantity of valid data. In further detail, in the first refresh unit 46, the rows 460, 462, 464 and 466 store valid data, and the row 468 is available. The second refresh unit 47 stores a second quantity of valid data. In further detail, in the second refresh unit 47, the rows 470, 472 and 474 store valid data, and the rows 476 and 478 are available. The third refresh unit 48 stores a third quantity of valid data. In further detail, in the third refresh unit 48, the rows 480 and 482 store valid data, and the rows 484, 486 and 488 are available.

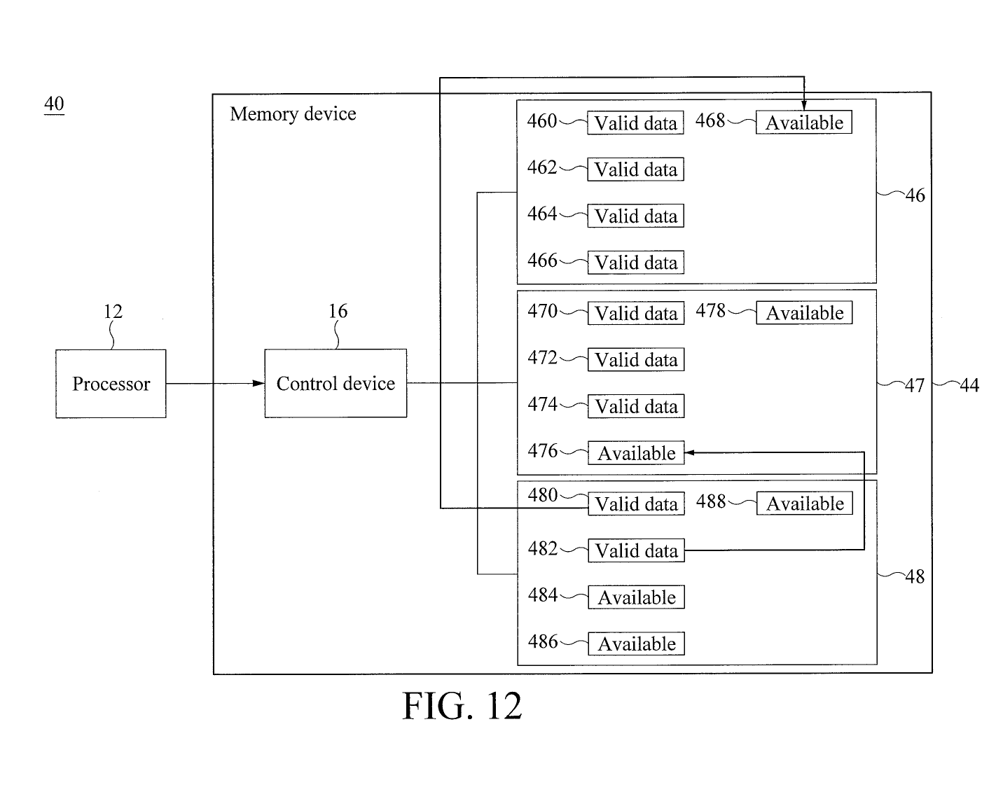

FIG. 12 is a block diagram illustrating a centralization operation of the memory device 40 shown in FIG. 10 based on the capacity status shown in FIG. 11, in accordance with some embodiments of the present disclosure. Referring to FIG. 12, the control device 16 determines that the first refresh unit 46 stores the greatest quantity of valid data, the second refresh unit 47 stores the second greatest quantity of valid data, and the third refresh unit 48 stores the smallest quantity of valid data. Accordingly, the control device 16 determines that the first refresh unit 46 has highest priority to serve as a destination refresh unit, and the second refresh unit 47 has a middle priority to serve as the destination refresh unit, as discussed in the embodiment of FIG. 8.

Moreover, since the second refresh unit 47 stores the second greatest quantity of valid data, and the third refresh unit 48 stores the smallest quantity of valid data, valid data of the third refresh unit 48 has higher priority to be centralized into the destination refresh unit than valid data of the second refresh unit 47.

In operation, the control device 16 determines that capacity of the first refresh unit 46 is not sufficient to store all of valid data stored in the second refresh unit 47 and the third refresh unit 48. Since valid data of the third refresh unit 48 has a higher priority to be centralized, the second refresh unit 47 serves as the destination refresh unit. Accordingly, the control device 16 centralizes a portion of the all of valid data into the first refresh unit 46 and centralizes the remaining portion of the all of valid data into the second refresh unit 47. In further detail, the control device 16 centralizes the data stored in the row 480 of the third refresh unit 48 into the row 468 of the first refresh unit 46, and centralizes the data stored in the row 482 of the third refresh unit 48 into the row 476 of the second refresh unit 47.

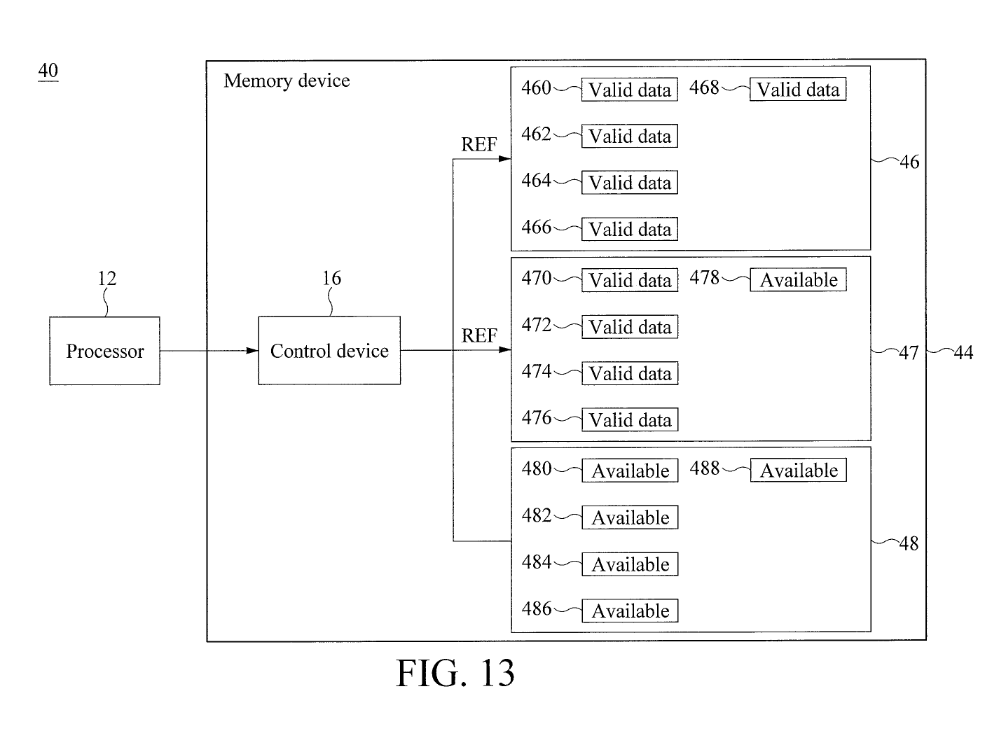

FIG. 13 is a block diagram illustrating a refresh operation of the memory device 40 shown in FIG. 10 after the centralization operation shown in FIG. 12, in accordance with some embodiments of the present disclosure. Referring to FIG. 13, the control device 16 ceases refreshing the third refresh unit 48, and continues refreshing the first refresh unit 46 and the second refresh unit 47, both of which serve as the destination refresh unit.

In the present disclosure, the control device 16 is able to centralize valid data from the third refresh unit 48 to the first refresh unit 46 and the second refresh unit 47. After the centralization operation is completed, the control device 16 ceases refreshing the third refresh unit 48, which no longer stores any valid data. As a result, the memory device 44 is relatively power efficient. Moreover, the control device 16 is further able to determine which refresh unit has priority to serve as a destination refresh unit, and the control device 16 is able to determine which refresh unit's valid data has higher priority to be centralized. As such, relatively few write and read operations are performed. As a result, the memory device 44 is even more power efficient.

In some existing DRAM devices, a DRAM controller of the DRAM device is unable to perform the centralization operation, and refreshes all refresh units in the DRAM device, despite the DRAM device being in a power saving mode. As a result, the existing DRAM devices have relatively low power efficiency.

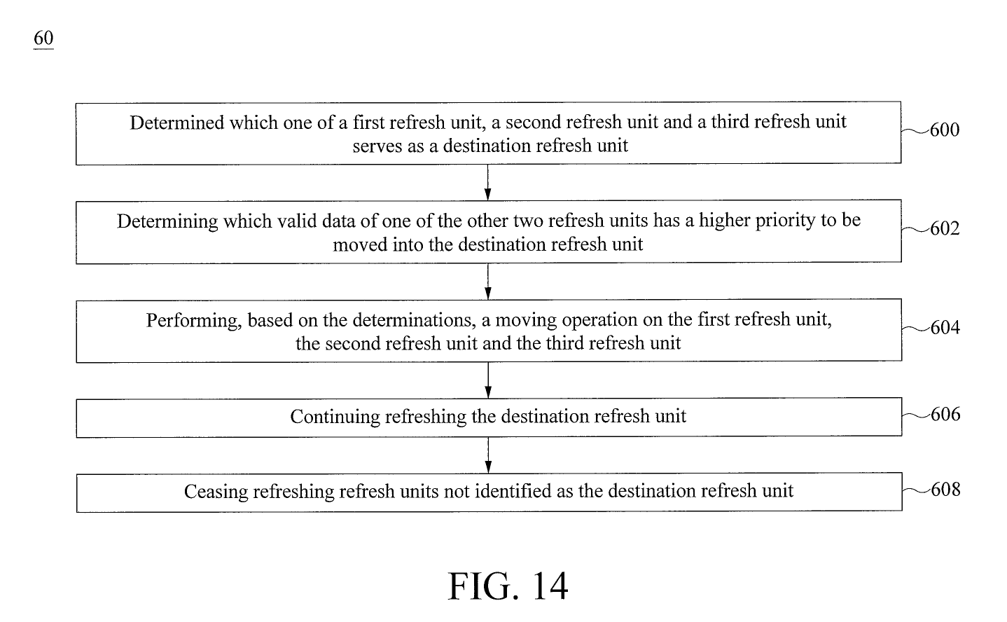

FIG. 14 is a flow diagram of another method 60, in accordance with some embodiments of the present disclosure. Referring to FIG. 14, the method 60 includes operations 600, 602, 604, 606 and 608. The method 60 begins with operation 600, in which it is determined which one of a first refresh unit, a second refresh unit and a third refresh unit serves as a destination refresh unit. The method 60 continues with operation 602, in which it is determined which valid data of one of the other two refresh units has a higher priority to be centralized into the destination refresh unit. The method 60 proceeds to operation 604, in which a centralization operation is performed on the first refresh unit, the second refresh unit and the third refresh unit based on the determinations in operations 600 and 602. The method 60 continues with operation 606, in which the destination refresh unit continues to be refreshed. The method 60 concludes with operation 608, in which refresh units not identified as the destination refresh unit cease to be refreshed.

In the present disclosure, valid data is able to be centralized into the destination refresh unit. After the centralization operation is completed, only the destination refresh unit continues to be refreshed. As a result, by using the method 60 to operate a memory device, the memory device has relatively high power efficiency. Moreover, it is possible to determine which data of a refresh unit has the higher priority to be centralized. As a result, the memory device is even more power efficient.

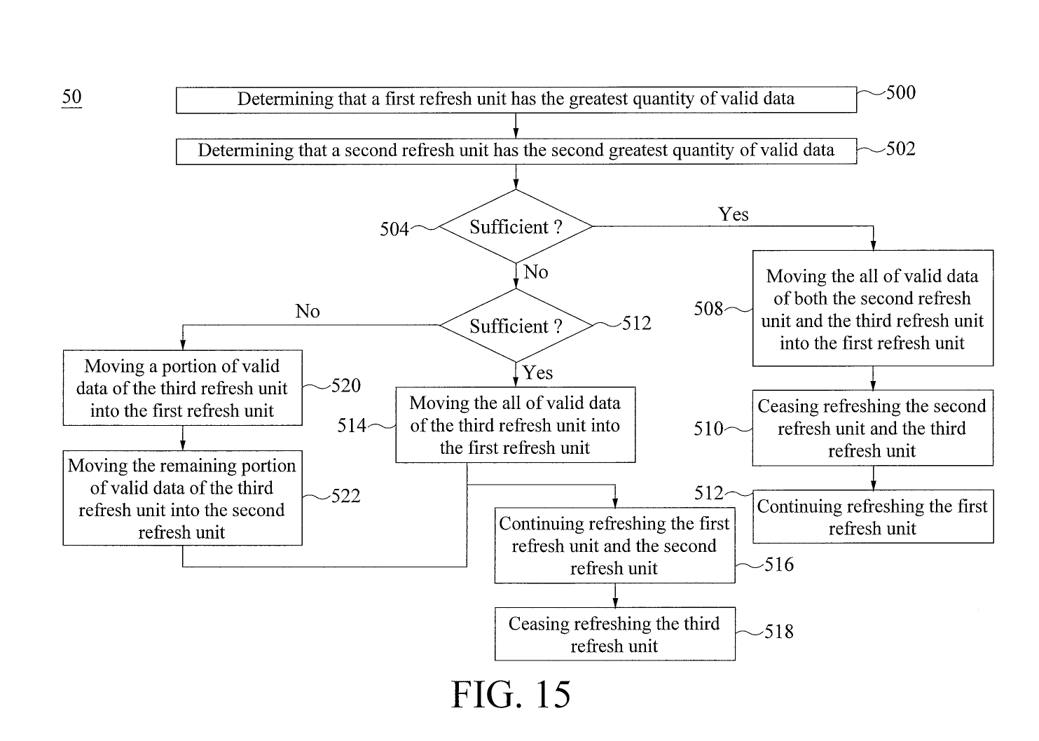

FIG. 15 is a flow diagram of yet another method 50, in accordance with some embodiments of the present disclosure. Referring to FIG. 15, the method 50 includes operations 500, 502, 504, 506, 508, 510, 512, 514, 516, 518, 520 and 522. The method 50 begins with operation 500, in which it is determined that a first refresh unit stores a greater quantity of valid data than a second refresh unit and a third refresh unit.

The method 50 continues with operation 502, in which it is determined that the second refresh unit stores the second greatest quantity of valid data, greater than the third refresh unit.

The method 50 continues with operation 504, in which it is determined whether a capacity of the first refresh unit is sufficient to store all of valid data stored in the second refresh unit and the third refresh unit. If negative, the operation 504 proceeds to operation 512. If affirmative, the operation 504 proceeds to operation 506, in which the all of valid data stored in the second refresh unit and the third refresh unit are centralized into the first refresh unit.

In operation 512, it is determined whether capacity of the first refresh unit is sufficient to store all of valid data stored only in the third refresh unit determined as a refresh unit storing the smallest quantity of valid data. If affirmative, the method 50 proceeds to operation 514, in which the all of valid data stored in the third refresh unit are centralized into the first refresh unit. If negative, the method 50 proceeds to operation 520, in which a portion of valid data stored in the third refresh unit is centralized into the first refresh unit. Subsequent to operation 520, in operation 522, the remaining portion of valid data stored in the third refresh unit is centralized into the second refresh unit.

In operation 516, the first refresh unit and the second refresh unit serving as a target refresh unit continue to be refreshed. In operation 518, the third refresh unit, which no longer stores any valid data, ceases to be refreshed.

In the present disclosure, valid data is able to be centralized into the destination refresh unit. After the centralization operation is completed, only the destination refresh unit continues to be refreshed. As a result, by using the method 50 to operate a memory device, the memory device has relatively high power efficiency. Moreover, it is possible to determine which data of a refresh unit has higher priority to be centralized. As a result, the memory device is even more power efficient.

In the present disclosure, the control device 16 is able to centralize valid data from the second refresh unit 33 and the third refresh unit 35 to the first refresh unit 31. After the centralization operation is completed, the control device 16 ceases refreshing the second refresh unit 33 and the third refresh unit 35, which no longer store any valid data. As a result, the memory device 34 has relatively high power efficiency. Moreover, the control device 16 is further able to determine which refresh unit has priority to serve as a destination refresh unit, and the control device 16 is able to determine which refresh unit's valid data has higher priority to be centralized. As such, relatively few write and read operations are performed. As a result, the memory device 34 is even more power efficient.

In some existing DRAM devices, a DRAM controller of the DRAM device is unable to perform the centralization operation, and refreshes all refresh units in the DRAM device despite the DRAM device being in a power saving mode. As a result, the existing DRAM devices have relatively low power efficiency.

One aspect of the present disclosure provides a DRAM. The DRAM includes a first refresh unit configured to store a first quantity of valid data; a second refresh unit configured to store a second quantity of valid data less than the first quantity of valid data; and a control device configured to determine that the first refresh unit stores a greater quantity of valid data than the second refresh unit, centralize valid data stored in the second refresh unit into the first refresh unit, and cease refreshing the second refresh unit, whose valid data was centralized into the first refresh unit.

Another aspect of the present disclosure provides a DRAM. The DRAM includes a first refresh unit configured to store a first quantity of valid data; a second refresh unit configured to store a second quantity of valid data; a third refresh unit configured to store a third quantity of valid data; and a control device configured to determine, based on the first quantity, the second quantity and the third quantity, which one of the first refresh unit, the second refresh unit and the third refresh unit serves as a destination refresh unit, into which valid data of the other two refresh units are centralized, determine, based on the first quantity, the second quantity and the third quantity, which valid data of one of the other two refresh units has a higher priority to be centralized into the destination refresh unit than the other one of the other two refresh units, perform, based on the determinations, a centralization operation on the first refresh unit, the second refresh unit and the third refresh unit, continue refreshing the destination refresh unit, and cease refreshing refresh units not identified as the destination refresh unit.

Another aspect of the present disclosure provides a method. The method includes determining that a first refresh unit stores a greater quantity of valid data than a second refresh unit; centralizing valid data stored in the second refresh unit into the first refresh unit; and ceasing refreshing the second refresh unit, whose valid data was centralized into the first refresh unit.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A dynamic random access memory (DRAM), comprising:
a first refresh unit having a first quantity of valid data;
a second refresh unit having a second quantity of valid data less than the first quantity of valid data; and
a control device configured to determine that the first refresh unit has a greater quantity of valid data than the second refresh unit, move valid data of the second refresh unit into the first refresh unit, and cease refreshing the second refresh unit whose valid data was moved into the first refresh unit.

2. The DRAM of claim 1, wherein the control device is configured to continue refreshing the first refresh unit, which stores the moved valid data.

3. The DRAM of claim 1, wherein the control device is configured to move valid data of the second refresh unit into the first refresh unit by providing to the first refresh unit the same valid data as that of the second refresh unit.

4. The DRAM of claim 3, wherein the control device is configured to move valid data of the second refresh unit into the first refresh unit during refreshing the second refresh unit.

5. The DRAM of claim 1, wherein the control device is configured to establish an updated relationship between a logical address and an updated physical address associated with the moved valid data, and access the first refresh unit based on the updated relationship when the control device is to access the moved valid data.

6. The DRAM of claim 5, wherein the control device is configured to remove a relationship between the logical address and an initial physical address associated with valid data of the second refresh unit when the control device establishes the updated relationship.

7. The DRAM of claim 1, further comprising:
a third refresh unit having a third quantity of valid data, wherein the second quantity of valid data is greater than the third quantity of valid data,
wherein the control device is further configured to determine that the first refresh unit has the greatest quantity of valid data,
wherein when the control device determines that capacity of the first refresh unit is sufficient to store all of valid data of the second refresh unit and the third refresh unit, the control device move the all of valid data to the first refresh unit, ceases refreshing the second refresh unit and the third refresh unit, and continues refreshing the first refresh unit.

8. The DRAM of claim 1, further comprising:
a third refresh unit having a third quantity of valid data, wherein the second quantity of valid data is greater than the third quantity of valid data,
wherein the control device is further configured to determine that the first refresh unit has the greatest quantity of valid data, and the second refresh unit has the second greatest quantity of valid data,
wherein when the control device determines that the first refresh unit has sufficient capacity to store all of valid data of only the third refresh unit, the control device moves the all of valid data to the first refresh unit, ceases refreshing the third refresh unit, and continues refreshing the first refresh unit and the second refresh unit.

9. The DRAM of claim 1, further comprising:
a third refresh unit having a third quantity of valid data less than the second quantity of valid data,
wherein the control device is further configured to determine that the first refresh unit has the greatest quantity of valid data, and the second refresh unit has the second greatest quantity of valid data,
wherein when the control device determines that capacity of the first refresh unit is not sufficient to store all of valid data of only the third refresh unit, the control device moves a portion of the all of valid data into the first refresh unit and moves the remaining portion of the all of valid data into the second refresh unit, ceases refreshing the third refresh unit, and continues refreshing the first refresh unit and the second refresh unit.

10. A dynamic random access memory (DRAM), comprising:
a first refresh unit having a first quantity of valid data;
a second refresh unit having a second quantity of valid data;
a third refresh unit having a third quantity of valid data; and
a control device configured to determine, based on the first quantity, the second quantity and the third quantity, which one of the first refresh unit, the second refresh unit and the third refresh unit serves as a destination refresh unit, into which valid data of the other two refresh units are moved, determine, based on the first quantity, the second quantity and the third quantity, which valid data of one of the other two refresh units has a higher priority to be moved into the destination refresh unit than the other one of the other two refresh units, perform, based on the determinations, a centralization operation on the first refresh unit, the second refresh unit and the third refresh unit, continue refreshing the destination refresh unit, and cease refreshing refresh units not identified as the destination refresh unit.

11. The DRAM of claim 10, wherein when the first quantity of valid data is greater than both the second quantity of valid data and the third quantity of valid data, the control device determines that the first refresh unit is the destination refresh unit.

12. The DRAM of claim 11, wherein when the second quantity of valid data is greater than the third quantity of valid data, the control device determines that valid data of the third refresh unit has higher priority than valid data of the second refresh unit.

13. A method, comprising:
determining that a first refresh unit has a greater quantity of valid data than a second refresh unit;
moving valid data of the second refresh unit into the first refresh unit; and
ceasing refreshing the second refresh unit whose valid data was moved into the first refresh unit.

14. The method of claim 13, further comprising:
refreshing the first refresh unit storing the moved valid data.

15. The method of claim 13, wherein the moving valid data stored in the second refresh unit into the first refresh unit includes:
moving valid data of the second refresh unit into the first refresh unit by providing to the first refresh unit the same valid data as that of the second refresh unit.

16. The method of claim 15, wherein the moving valid data of the second refresh unit into the first refresh unit includes:
moving valid data of the second refresh unit into the first refresh unit during refreshing the second refresh unit.

17. The method of claim 13, further comprising:
establishing an updated relationship between a logical address and an updated physical address associated with the moved valid data; and
accessing the first refresh unit based on the updated relationship when the moved valid data is to be accessed.

18. The method of claim 13, further comprising:
determining that the first refresh unit has the greatest quantity of valid data;
moving all of valid data of the second refresh unit and the third refresh unit to the first refresh unit when it is determined that capacity of the first refresh unit is sufficient to store the all of valid data;
ceasing refreshing the second refresh unit when it is determined that capacity of the first refresh unit is sufficient to store the all of valid data; and
continuing to refresh the first refresh unit when it is determined that capacity of the first refresh unit is sufficient to store the all of valid data.

19. The method of claim 13, further comprising:
determining that the first refresh unit has the greatest quantity of valid data;
determining that the second refresh unit has the second greatest quantity of valid data;
moving all of valid data of only the third refresh unit to the first refresh unit when it is determined that capacity of the first refresh unit is sufficient to store the all of valid data of the third refresh unit;
ceasing refreshing the third refresh unit when it is determined that capacity of the first refresh unit is sufficient to store the all of valid data of the third refresh unit; and
continuing to refresh the first refresh unit and the second refresh unit when it is determined that capacity of the first refresh unit is sufficient to store the all of valid data of the third refresh unit.

20. The method of claim 13, further comprising:
determining that the first refresh unit has the greatest quantity of valid data;
determining that the second refresh unit has the second greatest quantity of valid data;
moving a portion of all of valid data of the third refresh unit into the first refresh unit when it is determined that capacity of the first refresh unit is not sufficient to store the all of valid data of the third refresh unit;
moving the remaining portion of the all of valid data stored in the third refresh unit into the second refresh unit when it is determined that capacity of the first refresh unit is not sufficient to store the all of valid data of the third refresh unit;
ceasing to refresh the third refresh unit when it is determined that capacity of the first refresh unit is not sufficient to store the all of valid data of the third refresh unit; and
continuing to refresh the first refresh unit and the second refresh unit when it is determined that capacity of the first refresh unit is not sufficient to store the all of valid data of the third refresh unit.
